(19) United States
(12) Patent Application Publication
(10) Pub. No.: US 2007/0289626 A1
(43) Pub. Date: Dec. 20, 2007

(54) PHOTOVOLTAIC CELLS

(75) Inventors: Christoph Brabec, Linz (AT); Eitan C. Zeira, Hollis, NH (US)

Correspondence Address: FISH & RICHARDSON PC, P.O. BOX 1022, MINNEAPOLIS, MN, 55440-1022, US

(73) Assignee: Konarka Technologies, Inc., Lowell, MA (US)

(21) Appl. No.: 11/765,293

(22) Filed: Jun. 19, 2007

Related U.S. Application Data
(60) Provisional application No. 60/815,104, filed on Jun. 20, 2006.

(51) Int. Cl. H01L 31/00

(52) U.S. Cl. 136/263

(57) ABSTRACT

Photovoltaic cells containing electrically conductive particles in a electrode, as well as related components, systems, and methods, are disclosed.

### CROSS REFERENCE TO RELATED APPLICATION

This application claims priority to U.S. Provisional Application Ser. No. 60/815,104, filed Jun. 20, 2006, the contents of which are hereby incorporated by reference.

### TECHNICAL FIELD

This invention relates to photovoltaic cells containing electrically conductive particles in a electrode, as well as related components, systems, and methods.

### BACKGROUND

Photovoltaic cells are commonly used to transfer energy in the form of light into energy in the form of electricity. A typical photovoltaic cell includes a photoactive material disposed between two electrodes. Generally, light passes through one or both of the electrodes to interact with the photoactive material. As a result, the ability of one or both of the electrodes to transmit light (e.g., light at one or more wavelengths absorbed by a photoactive material) can limit the overall efficiency of a photovoltaic cell. In many photovoltaic cells, a film of semiconductive material (e.g., indium tin oxide) is used to form the electrode(s) through which light passes because, although the semiconductive material can have a lower electrical conductivity than electrically conductive materials, the semiconductive material can transmit more light than many electrically conductive materials.

### SUMMARY

In one aspect, the invention features an article that includes a first electrode, a second electrode containing a plurality of electrically conductive particles, and a photoactive layer between the first and second electrodes. At least some of the electrically conductive particles are coated with a self-assembled layer or a compound that includes at least one moiety selected from the group consisting of thiol, siloxane, amino, nitrate, carboxylate, phosphate, and sulfonate. The article is configured as a photovoltaic cell.

In another aspect, the invention features an article that includes a first electrode, a second electrode comprising a plurality of electrically conductive particles, a first photoactive layer between the first and second electrodes; and a second photoactive layer between the first photoactive layer and the second electrode. At least some of the electrically conductive particles are coated with a self-assembled layer or a compound that comprises at least one moiety selected from the group consisting of thiol, siloxane, amino, nitrate, carboxylate, phosphate, and sulfonate. The article is configured as a photovoltaic cell.

In another aspect, the invention features a method that includes disposing a photoactive layer between two electrodes to form a photovoltaic cell. At least one of the electrodes contains a plurality of electrically conductive particles and at least some of the electrically conductive particles are coated with a self-assembled layer or a compound that contains at least one moiety selected from the group consisting of thiol, siloxane, amino, nitrate, carboxylate, phosphate, and sulfonate.

In another aspect, the invention features a method that includes applying a solution containing a compound onto a layer comprising a plurality of electrically conductive particles to form a first electrode, and disposing a photoactive layer between the first electrode and a second electrode to form a photovoltaic cell. The compound contains at least one moiety selected from the group consisting of thiol, siloxane, amino, nitrate, carboxylate, phosphate, and sulfonate.

In still another aspect, the invention features a method that includes applying a solution onto a first layer containing a plurality of electrically conductive particles to form a first electrode, and disposing a photoactive layer between the first electrode and a second electrode to form a photovoltaic cell. The first electrode includes the first layer and a self-assembled layer.

Embodiments can include one or more of the following features.

In some embodiments, substantially all of the electrically conductive particles are coated with the compound.

In some embodiments, the compound comprises a thiol moiety.

In some embodiments, the compound is an alkanethiol compound (e.g., hexadecanethiol) or a perfluorinated alkanethiol compound (e.g., 1H,1H,2H,2H-perfluorodecanethiol).

In some embodiments, the compound is of the formula R—SH, in which R is C₁-C₂₀ alkyl, C₂-C₂₀ alkenyl, C₂-C₂₀ alkynyl, C₃-C₂₀ cycloalkyl, C₃-C₂₀ cycloalkenyl, C₁-C₂₀ heterocycloalkyl, C₁-C₂₀ heterocycloalkenyl, aryl, or heteroaryl. For example, R can be C₁-C₁₀ alkyl optionally substituted with F.

In some embodiments, the electrically conductive particles are formed of a metal, such as silver, gold, platinum, palladium, copper, or an alloy thereof.

In some embodiments, the electrically conductive particles are formed of a metal oxide. For example, the metal oxide can include indium oxide, tin oxide, indium tin oxide, zinc oxide, magnesium oxide, or a mixture thereof.

In some embodiments, the electrically conductive particles have an average diameter of at least about 0.5 microns or at most about 10 microns.

In some embodiments, the second electrode further includes a polymer. In certain embodiments, the polymer includes a polyester, a polyvinyl chloride, a polyvinyl acetate, a poly(ethylene-vinyl acetate), a polyurethane, a poly(styrene-butadiene), a polyacrylic, or a copolymer thereof.

In some embodiments, the second electrode further includes a surfactant.

In some embodiments, the photoactive layer includes an electron donor material and an electron acceptor material.

In some embodiments, the electron donor material includes a polymer. For example, the polymer can be selected from the group consisting of polythiophenes, polyanilines, polycarbazoles, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxaline, polybenzoisothiazole, polybenzothiazole, polythienothiophene, poly(thienothiophene oxide), polydithienothiophene, poly(dithienothiophene oxide)s, polytetrahydroisoindoles, and copolymers thereof In certain embodiments, the electron donor material includes poly(3-hexylthiophene) or poly(cyclopentadithiophene-co-benzothiadiazole).

In some embodiments, the electron acceptor material includes a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof In certain embodiments, the electron acceptor material includes a substituted fullerene (e.g., PCBM).

In some embodiments, the article further includes a hole carrier layer between the first electrode and the photoactive layer. The hole carrier layer can include a polymer, such as that selected from the group consisting of polythiophenes, polyanilines, polycarbazoles, polyvinylcarbazoles, polyphenylenes, polyphenylvinylenes, polysilanes, polythienylenevinylenes, polyisothianaphthanenes, and copolymers thereof. In certain embodiments, the polymer includes poly(3,4-ethylene dioxythiophene).

In some embodiments, the article is configured as a tandem photovoltaic cell.

In some embodiments, the method further includes immersing at least some of the electrically conductive particles in a solution containing the compound before the disposing step. In certain embodiments, the solution includes an organic solvent.

In some embodiments, the method further includes incorporating the electrically conductive particles into an ink between the immersing step and the disposing step.

In some embodiments, the ink includes a polymer. In certain embodiments, the polymer includes a polyester, a styrene-butadiene polymer, or an acrylic polymer.

In some embodiments, the ink includes a surfactant.

In some embodiments, the ink includes comprises a solvent. In certain embodiments, the solvent includes an alcohol, a glycol ether, a glycol ether acetate, or an ester.

In some embodiments, the method includes a roll-to-roll process.

In some embodiments, the solution includes an organic solvent.

In some embodiments, the solution includes at most about 0.05 wt % of the compound.

In some embodiments, the method further includes drying the solution applied onto the layer to form a coating after the applying step. In certain embodiments, the drying is carried out at a temperature of at most about 150° C.

Embodiments can provide one or more of the following advantages.

In some embodiments, a self-assembled layer can modify the work function of the electrically conductive particles such that the particles form an ohmic contact with the underlying layer (e.g., a photoactive layer or a hole blocking layer). As a result, the self-assembled layer allows high work function metals (e.g., silver) to be used as a top electrode of a photovoltaic cell even though such metals by themselves typically cannot be used as an electrode due to lack of ohmic contact with the materials used in the photovoltaic cell. Since high work function metals generally are not oxidized in air, this approach reduces the level of barriers required for encapsulation of the top electrode.

In some embodiments, the surfactant can facilitate the dispersion of the electrically conductive particles in the polymer to form a uniform electrode.

In some embodiments, at least some of the methods described above can be readily incorporated in a continuous manufacturing process, such as a roll-to-roll process. In such embodiments, the methods can result in higher production efficiency and lower production costs than a batch-to-batch manufacturing process.

The details of one or more embodiments of the invention are set forth in the accompanying drawings and the description below. Other features and advantages of the invention will be apparent from the description, drawings, and claims.

### DESCRIPTION OF DRAWINGS

FIG. 1 is a cross-sectional view of an embodiment of a organic photovoltaic cell.

FIG. 2 is a cross-sectional view of an embodiment of a tandem photovoltaic cell.

FIG. 3 is a cross-sectional view of an embodiment of a dye sensitized solar cell.

FIG. 4 is a schematic of a system containing multiple photovoltaic cells electrically connected in series.

FIG. 5 is a schematic of a system containing multiple photovoltaic cells electrically connected in parallel.

Like reference symbols in the various drawings indicate like elements.

### DETAILED DESCRIPTION

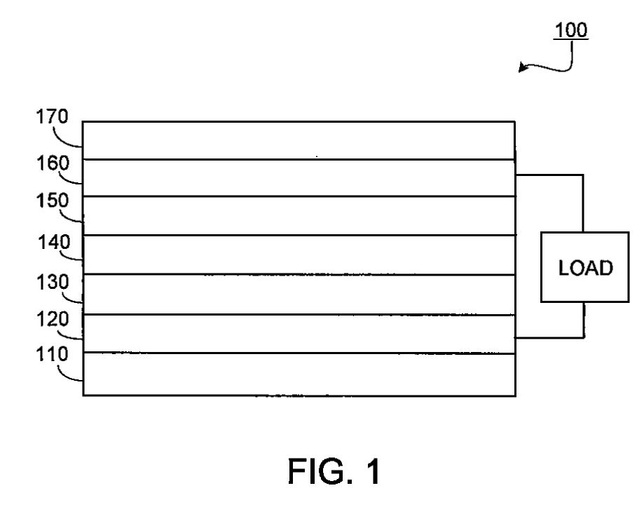

FIG. 1 shows a cross-sectional view of a organic photovoltaic cell 100 that includes a substrate 110, a cathode 120, a hole carrier layer 130, a photoactive layer 140 (e.g., containing an organic electron acceptor material and an organic electron donor material), a hole blocking layer 150, an anode 160, and a substrate 170.

In general, during use, light can impinge on the surface of substrate 110, and pass through cathode 120, and hole carrier layer 130. The light then interacts with photoactive layer 140, causing electrons to be transferred from the electron donor material (e.g., P3HT) to the electron acceptor material (e.g., PCBM). The electron acceptor material then transmits the electrons through hole blocking layer 150 to anode 160, and the electron donor material transfers holes through hole carrier layer 130 to cathode 120. Anode 160 and cathode 120 are in electrical connection via an external load so that electrons pass from anode 160, through the load, and to cathode 120.

Anode 160 generally includes a binder polymer and a plurality of electrically conductive particles dispersed in the binder polymer. The electrically conductive particles can be in any suitable form, such as nanoparticles, nanorods, or flakes.

In general, the electrically conductive particles include a core and a coating. In some embodiments, the core is formed of electrically conductive metals and electrically conductive metal oxides. Exemplary electrically conductive metals include silver, gold, platinum, palladium, copper, or an alloy thereof. Exemplary electrically conductive metal oxides include indium oxide, tin oxide, indium tin oxide, zinc oxide, magnesium oxide, or a mixture thereof. The electrically conductive metal oxides can be either undoped or doped. Exemplary dopants include salts or acids of fluoride, chloride, bromide, and iodide.

In some embodiments, the coating is a self-assembled layer. The term “self-assembled layer” used herein refers to a layer of closely-packed molecules that sticks to a surface in an orderly and closely-packed fashion. In some embodiments, the self-assembled layer is formed of a compound contains at least a thiol, siloxane, amino, nitrate, carboxylate, phosphate, or sulfonate moiety. Without wishing to be bound by theory, it is believed that the compound forms a self-assembled layer by covalently bonding to the surface of the electrically conductive particles. In some embodiments, the compound is of the formula R—SH, in which R is C₁-C₂₀ alkyl, C₂-C₂₀ alkenyl, C₂-C₂₀ alkynyl, C₃-C₂₀ cycloalkyl, C₃-C₂₀ cycloalkenyl, C₁-C₂₀ heterocycloalkyl, C₁-C₂₀ heterocycloalkenyl, aryl, or heteroaryl. For example, R can be C₁-C₁₀ alkyl optionally substituted with F. In certain embodiments, the compound is an alkanethiol compound (e.g., hexadecanethiol) or a perfluorinated alkanethiol compound (e.g., 1H,1H,2H,2H-perfluorodecanethiol). In some embodiments, all of the electrically conductive particles are coated with a self-assembled layer.

In some embodiments, the thickness of the self-assembled layer is at least about 1 nm (e.g., at least about 5 nm, at least about 10 nm, at least about 15 nm, or at least about 20 nm) or at most about 50 nm (e.g., at most about 40 nm, at most about 30 nm, at most about 20 nm, or at most about 10 nm).

In some embodiments, the electrically conductive particles have an average diameter of at least about 0.5 microns (e.g., at least about 1 micron, at least about 3 microns, at least about 5 microns, or at least about 7 microns) or at most about 10 microns (e.g., at most about 8 microns, at most about 6 microns, at most about 4 microns, or at most about 2 microns).

In general, the binder polymer can be any polymer suitable for dispersing the electrically conductive particles. Exemplary binder polymers include a polyester, a polyvinyl chloride, a polyvinyl acetate, a poly(ethylene-vinyl acetate), a polyurethane, a poly(styrene-butadiene), a polyacrylic, or a copolymer thereof.

In some embodiments, the second electrode can further include a surfactant. Exemplary surfactant includes TRITON X-100 (Union Carbide Corporation, Houston, Texas), DYNOL 604 or DYNOL 607 (Air Products and Chemicals, Inc., Allentown, Pa.), SURFYNOL (Air Products and Chemicals, Inc., Allentown, Pa.), and ZONYL (Dupont, Wilmington, Del.). Without wishing to be bound by theory, it is believed that the surfactant can facilitate the dispersion of the electrically conductive particles in the binder polymer.

One advantage of coating a self-assembled layer onto electrically conductive particles is that the self-assembled layer modifies the work function of the electrically conductive particles such that the particles form an ohmic contact with its underlying layer (e.g., a photoactive layer or a hole blocking layer). As a result, the self-assembled layer allows high work function metals (e.g., silver) to be used as a top electrode of a photovoltaic cell even though such metals by themselves typically cannot be used as an electrode due to lack of ohmic contact with the materials used in the photovoltaic cell. Since high work function metals generally are not easily oxidized in air, this approach reduces the level of barriers required for encapsulation of the top electrode.

In some embodiments, anode 160 includes a mesh electrode, in which the mesh is formed of the electrically conductive particles. Examples of mesh electrodes are described in commonly owned co-pending U.S. Patent Application Publication Nos. 20040187911 and 20060090791, the contents of which are hereby incorporated by reference.

In some embodiments, anode 160 can be prepared by the following method: Electrically conductive particles (e.g., silver particles) are first immersed in a solution containing a first organic solvent (e.g., ethanol) and a compound having self-assembled properties (e.g., hexadecanethiol) for a certain amount of time (e.g., about 30 hours). The particles are then isolated from the solution and rinsed (e.g., by using ethanol). The particles are subsequently dispersed in an ink that includes a binder polymer and optionally a surfactant in a second organic solvent. The second organic solvent can include an alcohol (e.g., methanol, ethanol, isopropanol, or n-butanol), a glycol ether (e.g., ethylene glycol monomethyl ether, propylene glycol monomethyl ether, or diethylene glycol monomethyl ether), a glycol ether acetate (e.g., diethylene glycol monoethyl ether acetate, propylene glycol monomethyl ether acetate, or propylene glycol monoethyl ether acetate), or an ester (e.g., dimethyl adipate, dimethyl glutarate, dimethyl succinate). Anode 160 can then be formed by applying the ink on hole blocking layer 150 through a coating process (e.g., gravure coating or slot coating) in a continuous manufacturing process (e.g., a roll-to-roll process). One advantage of the above process is that it can be readily incorporated in a continuous manufacturing process. In such embodiments, it can result in higher production efficiency and lower production costs than a batch-to-batch manufacturing process.

In some embodiments, anode 160 can be prepared by the following method: a suitable amount of a compound having self-assembled properties (e.g., hexadecanethiol) is added to a first ink containing an organic solvent (e.g., ethanol) used in a roll-to-roll process for manufacturing photovoltaic cells. The first ink can optionally contain a binder polymer and a surfactant, such as those described above. The amount of the compound can be calculated based on the amount of electrically conductive particles (e.g., silver particles) to be coated. When preparing an electrode, electrically conductive particles can first be coated or printed on an underlying substrate by applying a second ink containing electrically conductive particles. The first ink can then be coated (e.g., by slot coating) onto the electrically conductive particles at a suitable rate (e.g., about 0.05 ml/min). An electrode can subsequently be prepared after slow drying the coating at a low web speed (e.g., about 1-500 ft/min such as about 1-5 ft/min) and a low drying temperature (about 50-70° C. or 100-150° C.).

Turning to other components of photovoltaic cell 100, substrate 110 is generally formed of a transparent material. As referred to herein, a transparent material is a material which, at the thickness used in a photovoltaic cell 100, transmits at least about 60% (e.g., at least about 70%, at least about 75%, at least about 80%, at least about 85%) of incident light at a wavelength or a range of wavelengths used during operation of the photovoltaic cell. Exemplary materials from which substrate 110 can be formed include polyethylene terephthalates, polyimides, polyethylene naphthalates, polymeric hydrocarbons, cellulosic polymers, polycarbonates, polyamides, polyethers, and polyether ketones. In certain embodiments, the polymer can be a fluorinated polymer. In some embodiments, combinations of polymeric materials are used. In certain embodiments, different regions of substrate 110 can be formed of different materials.

In general, substrate 110 can be flexible, semi-rigid or rigid (e.g., glass). In some embodiments, substrate 110 has a flexural modulus of less than about 5,000 megaPascals (e.g., less than about 1,000 megaPascals or less than about 500 megaPascals). In certain embodiments, different regions of substrate 110 can be flexible, semi-rigid, or inflexible (e.g., one or more regions flexible and one or more different regions semi-rigid, one or more regions flexible and one or more different regions inflexible).

Typically, substrate 110 is at least about one micron (e.g., at least about five microns, at least about 10 microns) thick and/or at most about 1,000 microns (e.g., at most about 500 microns thick, at most about 300 microns thick, at most about 200 microns thick, at most about 100 microns, at most about 50 microns) thick.

Generally, substrate 110 can be colored or non-colored. In some embodiments, one or more portions of substrate 110 is/are colored while one or more different portions of substrate 110 is/are non-colored.

Substrate 110 can have one planar surface (e.g., the surface on which light impinges), two planar surfaces (e.g., the surface on which light impinges and the opposite surface), or no planar surfaces. A non-planar surface of substrate 110 can, for example, be curved or stepped. In some embodiments, a non-planar surface of substrate 110 is patterned (e.g., having patterned steps to form a Fresnel lens, a lenticular lens or a lenticular prism).

Cathode 120 is generally formed of an electrically conductive material. Exemplary electrically conductive materials include electrically conductive metals, electrically conductive alloys, electrically conductive polymers, and electrically conductive metal oxides. Exemplary electrically conductive metals include gold, silver, copper, aluminum, nickel, palladium, platinum, and titanium. Exemplary electrically conductive alloys include stainless steel (e.g., 332 stainless steel, 316 stainless steel), alloys of gold, alloys of silver, alloys of copper, alloys of aluminum, alloys of nickel, alloys of palladium, alloys of platinum and alloys of titanium. Exemplary electrically conducting polymers include polythiophenes (e.g., PEDOT), polyanilines (e.g., doped polyanilines), polypyrroles (e.g., doped polypyrroles). Exemplary electrically conducting metal oxides include indium tin oxide, fluorinated tin oxide, tin oxide and zinc oxide. In some embodiments, combinations of electrically conductive materials are used.

In some embodiments, cathode 120 can include a mesh electrode. Examples of mesh electrodes are described in commonly owned co-pending U.S. Patent Application Publication Nos. 20040187911 and 20060090791, the contents of which are hereby incorporated by reference.

In some embodiments, cathode 120 is formed of a material used to prepare anode 160 described above.

Hole carrier layer 130 is generally formed of a material that, at the thickness used in photovoltaic cell 100, transports holes to cathode 120 and substantially blocks the transport of electrons to cathode 120. Examples of materials from which layer 130 can be formed include polythiophenes (e.g., PEDOT), polyanilines, polycarbazoles, polyvinylcarbazoles, polyphenylenes, polyphenylvinylenes, polysilanes, polythienylenevinylenes, polyisothianaphthanenes, and copolymers thereof. In some embodiments, hole carrier layer 130 can include combinations of hole carrier materials.

In general, the thickness of hole carrier layer 130 (i.e., the distance between the surface of hole carrier layer 130 in contact with photoactive layer 140 and the surface of cathode 120 in contact with hole carrier layer 130) can be varied as desired. Typically, the thickness of hole carrier layer 130 is at least 0.01 micron (e.g., at least about 0.05 micron, at least about 0.1 micron, at least about 0.2 micron, at least about 0.3 micron, or at least about 0.5 micron) and/or at most about five microns (e.g., at most about three microns, at most about two microns, or at most about one micron). In some embodiments, the thickness of hole carrier layer 130 is from about 0.01 micron to about 0.5 micron.

In some embodiments, photoactive layer 140 contains an electron acceptor material (e.g., an organic electron acceptor material) and an electron donor material (e.g., an organic electron donor material).

Examples of electron acceptor materials include fullerenes, inorganic nanoparticles, oxadiazoles, discotic liquid crystals, carbon nanorods, inorganic nanorods, polymers containing moieties capable of accepting electrons or forming stable anions (e.g., polymers containing CN groups or polymers containing CF₃ groups), and combinations thereof. In some embodiments, the electron acceptor material is a substituted fullerene (e.g., PCBM). In some embodiments, a combination of electron acceptor materials can be used in photoactive layer 140.

Examples of electron donor materials include conjugated polymers, such as polythiophenes, polyanilines, polycarbazoles, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxalines, polybenzoisothiazoles, polybenzothiazoles, polythienothiophenes, poly(thienothiophene oxide)s, polydithienothiophenes, poly(dithienothiophene oxide)s, polytetrahydroisoindoles, and copolymers thereof. In some embodiments, the electron donor material can be polythiophenes (e.g., poly(3-hexylthiophene)), polycyclopentadithiophenes, and copolymers thereof. In certain embodiments, a combination of electron donor materials can be used in photoactive layer 140.

In some embodiments, the electron donor materials or the electron acceptor materials can include a polymer having a first comonomer repeat unit and a second comonomer repeat unit different from the first comonomer repeat unit. The first comonomer repeat unit can include a cyclopentadithiophene moiety, a silacyclopentadithiophene moiety, a cyclopentadithiazole moiety, a thiazolothiazole moiety, a thiazole moiety, a benzothiadiazole moiety, a thiophene oxide moiety, a cyclopentadithiophene oxide moiety, a polythiadiazoloquinoxaline moiety, a benzoisothiazole moiety, a benzothiazole moiety, a thienothiophene moiety, a thienothiophene oxide moiety, a dithienothiophene moiety, a dithienothiophene oxide moiety, or a tetrahydroisoindoles moiety.

In some embodiments, the first comonomer repeat unit includes a cyclopentadithiophene moiety. In some embodiments, the cyclopentadithiophene moiety is substituted with at least one substituent selected from the group consisting of C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, and SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. For example, the cyclopentadithiophene moiety can be substituted with hexyl, 2-ethylhexyl, or 3,7-dimethyloctyl. In certain embodiments, the cyclopentadithiophene moiety is substituted at 4-position. In some embodiments, the first comonomer repeat unit can include a cyclopentadithiophene moiety of formula (1): 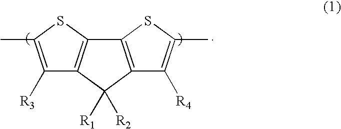
In formula (1), each of R₁, R₂, R₃, or R₄, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. For example, each of R₁ and R₂, independently, can be hexyl, 2-ethylhexyl, or 3,7-dimethyloctyl.

The second comonomer repeat unit can include a benzothiadiazole moiety, a thiadiazoloquinoxaline moiety, a cyclopentadithiophene oxide moiety, a benzoisothiazole moiety, a benzothiazole moiety, a thiophene oxide moiety, a thienothiophene moiety, a thienothiophene oxide moiety, a dithienothiophene moiety, a dithienothiophene oxide moiety, a tetrahydroisoindole moiety, a fluorene moiety, a silole moiety, a cyclopentadithiophene moiety, a fluorenone moiety, a thiazole moiety, a selenophene moiety, a thiazolothiazole moiety, a cyclopentadithiazole moiety, a naphthothiadiazole moiety, a thienopyrazine moiety, a silacyclopentadithiophene moiety, an oxazole moiety, an imidazole moiety, a pyrimidine moiety, a benzoxazole moiety, or a benzimidazole moiety. In some embodiments, the second comonomer repeat unit is a 3,4-benzo-1,2,5-thiadiazole moiety.

In some embodiments, the second comonomer repeat unit can include a benzothiadiazole moiety of formula (2), a thiadiazoloquinoxaline moiety of formula (3), a cyclopentadithiophene dioxide moiety of formula (4), a cyclopentadithiophene monoxide moiety of formula (5), a benzoisothiazole moiety of formula (6), a benzothiazole moiety of formula (7), a thiophene dioxide moiety of formula (8), a cyclopentadithiophene dioxide moiety of formula (9), a cyclopentadithiophene tetraoxide moiety of formula (10), a thienothiophene moiety of formula (11), a thienothiophene tetraoxide moiety of formula (12), a dithienothiophene moiety of formula (13), a dithienothiophene dioxide moiety of formula (14), a dithienothiophene tetraoxide moiety of formula (15), a tetrahydroisoindole moiety of formula (16), a thienothiophene dioxide moiety of formula (17), a dithienothiophene dioxide moiety of formula (18), a fluorene moiety of formula (19), a silole moiety of formula (20), a cyclopentadithiophene moiety of formula (21), a fluorenone moiety of formula (22), a thiazole moiety of formula (23), a selenophene moiety of formula (24), a thiazolothiazole moiety of formula (25), a cyclopentadithiazole moiety of formula (26), a naphthothiadiazole moiety of formula (27), a thienopyrazine moiety of formula (28), a silacyclopentadithiophene moiety of formula (29), an oxazole moiety of formula (30), an imidazole moiety of formula (31), a pyrimidine moiety of formula (32), a benzoxazole moiety of formula (33), or a benzimidazole moiety of formula (34):

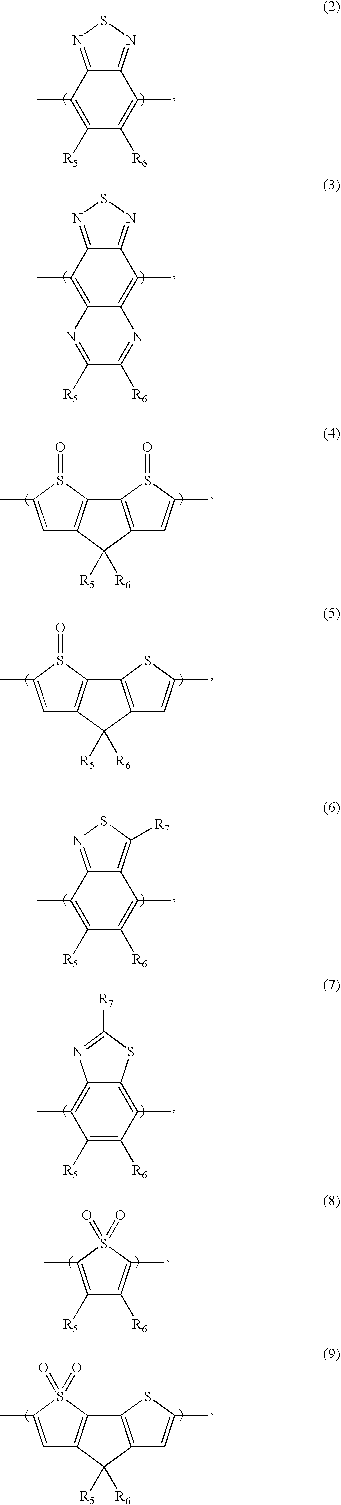

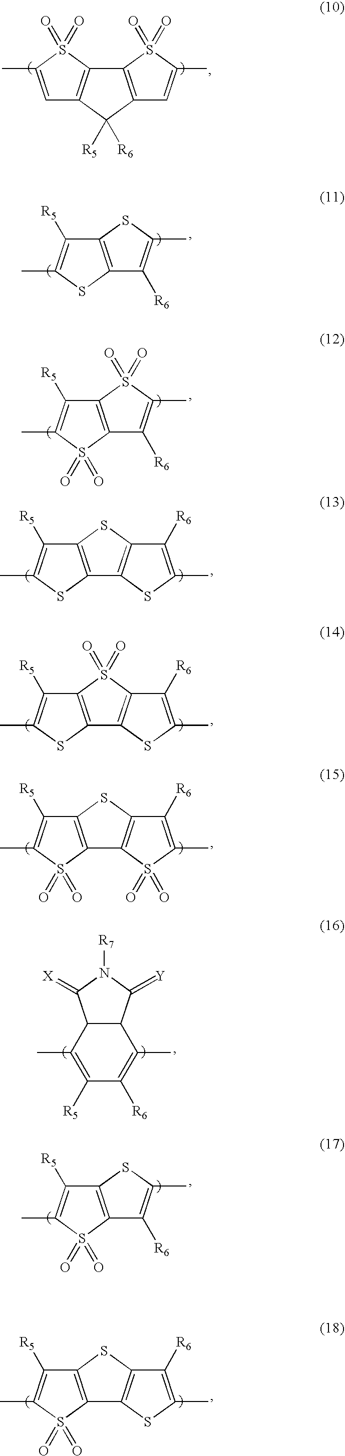

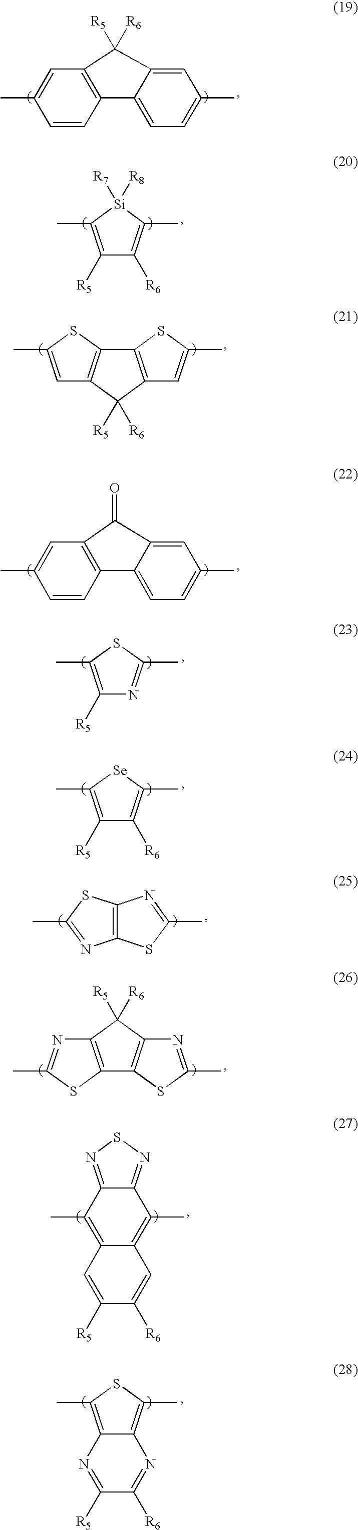

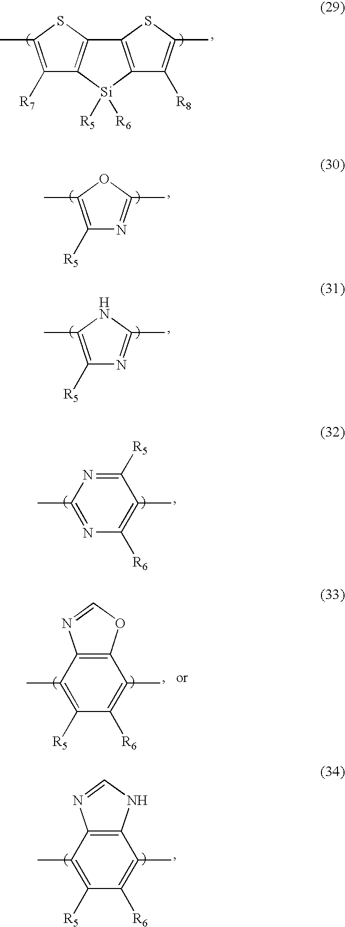

In the above formulas, each of X and Y, independently, is CH₂, O, or S; each of R₅ and R₆, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R, in which R is H, C₁-C₂₀ alkyl, C₁-C₂₀ alkoxy, aryl, heteroaryl, C₃-C₂₀ cycloalkyl, or C₁-C₂₀ heterocycloalkyl; and each of R₇ and R₈, independently, is H, C₁-C₂₀ alkyl, C₁-C₂₀ alkoxy, aryl, heteroaryl, C₃-C₂₀ cycloalkyl, or C₃-C₂₀ heterocycloalkyl. In some embodiments, the second comonomer repeat unit includes a benzothiadiazole moiety of formula (2), in which each of R₅ and R₆ is H.

The second comonomer repeat unit can include at least three thiophene moieties. In some embodiments, at least one of the thiophene moieties is substituted with at least one substituent selected from the group consisting of C₁-C₂₀ alkyl, C₁-C₂₀ alkoxy, aryl, heteroaryl, C₃-C₂₀ cycloalkyl, and C₃-C₂₀ heterocycloalkyl. In certain embodiments, the second comonomer repeat unit includes five thiophene moieties.

The polymer can further include a third comonomer repeat unit that contains a thiophene moiety or a fluorene moiety. In some embodiments, the thiophene or fluorene moiety is substituted with at least one substituent selected from the group consisting of C₁-C₂₀ alkyl, C₁-C₂₀ alkoxy, aryl, heteroaryl, C₃-C₂₀ cycloalkyl, and C₃-C₂₀ heterocycloalkyl.

In some embodiments, the polymer can be formed by any combination of the first, second, and third comonomer repeat units. In certain embodiments, the polymer can be a homopolymer containing any of the first, second, and third comonomer repeat units.

In some embodiments, the polymer can be 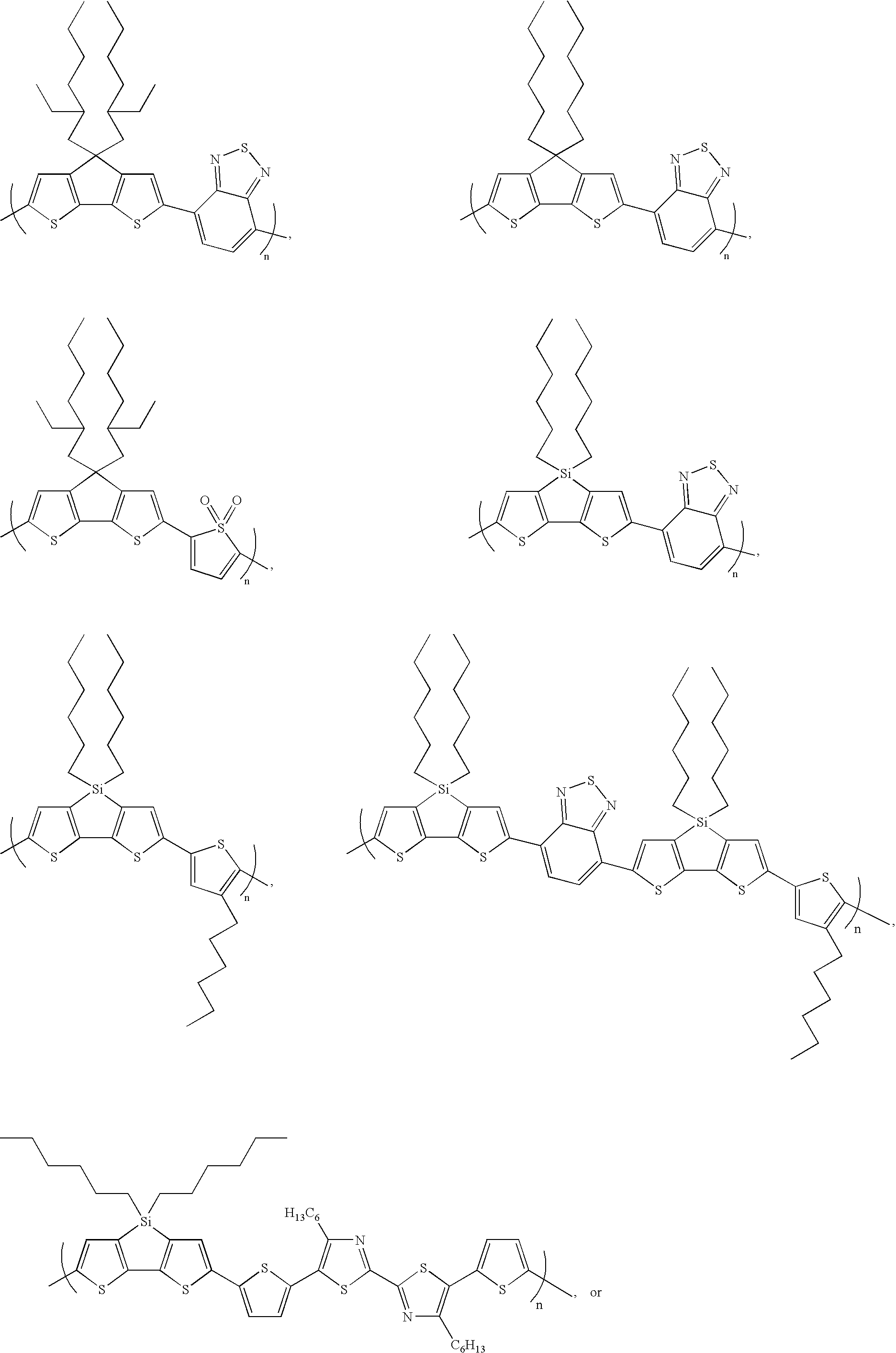 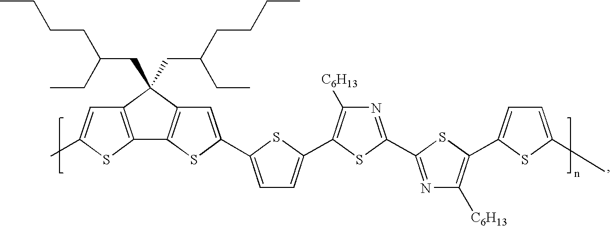
in which n can be an integer greater than 1.

The monomers for preparing the polymers mentioned herein may contain a non-aromatic double bond and one or more asymmetric centers. Thus, they can occur as racemates and racemic mixtures, single enantiomers, individual diastereomers, diastereomeric mixtures, and cis- or trans-isomeric forms. All such isomeric forms are contemplated.

The polymers described above can be prepared by methods known in the art, such as those described in commonly owned co-pending U.S. application Ser. No. 11/601,374, the contents of which are hereby incorporated by reference. For example, a copolymer can be prepared by a cross-coupling reaction between one or more comonomers containing two alkylstannyl groups and one or more comonomers containing two halo groups in the presence of a transition metal catalyst. As another example, a copolymer can be prepared by a cross-coupling reaction between one or more comonomers containing two borate groups and one or more comonomers containing two halo groups in the presence of a transition metal catalyst. The comonomers can be prepared by the methods know in the art, such as those described in commonly owned co-pending U.S. patent application Ser. No. 11/486,536, Coppo et al., Macromolecules 2003, 36, 2705-2711, and Kurt et al., J. Heterocycl. Chem. 1970, 6, 629, the contents of which are hereby incorporated by reference.

Without wishing to be bound by theory, it is believed that an advantage of the polymers described above is that their absorption wavelengths shift toward the red and near IR regions (e.g., 650-800 nm) of the electromagnetic spectrum, which is not accessible by most other conventional polymers. When such a polymer is incorporated into a photovoltaic cell together with a conventional polymer, it enables the cell to absorb the light in this region of the spectrum, thereby increasing the current and efficiency of the cell.

In some embodiments, photoactive layer 140 can contain an inorganic semiconductor material. In some embodiments, the inorganic semiconductor material includes group IV semiconductor materials, group III-V semiconductor materials, group II-VI semiconductor materials, chalcogen semiconductor materials, and semiconductor metal oxides. Examples of group IV semiconductor materials include amorphous silicon, crystalline silicon (e.g., microcrystalline silicon or polycrystalline silicon), and germanium. Examples of group III-V semiconductor materials include gallium arsenide and indium phosphide. Examples of group II-VI semiconductor materials include cadmium selenide and cadmium telluride. Examples of chalcogen semiconductor materials include copper indium selenide (CIS) and copper indium gallium selenide (CIGS). Examples of semiconductor metal oxides include copper oxides, titanium oxides, zinc oxides, tungsten oxides, molybdenum oxides, strontium copper oxides, or strontium titanium oxides. In certain embodiments, the bandgap of the semiconductor can be adjusted via doping. In some embodiments, the inorganic semiconductor material can include inorganic nanoparticles.

Generally, photoactive layer 140 is sufficiently thick to be relatively efficient at absorbing photons impinging thereon to form corresponding electrons and holes, and sufficiently thin to be relatively efficient at transporting the holes and electrons. In certain embodiments, photoactive layer 140 is at least 0.05 micron (e.g., at least about 0.1 micron, at least about 0.2 micron, at least about 0.3 micron) thick and/or at most about one micron (e.g., at most about 0.5 micron, at most about 0.4 micron) thick. In some embodiments, photoactive layer 140 is from about 0.1 micron to about 0.2 micron thick.

Photovoltaic cell 100 can optionally include hole blocking layer 150. Hole blocking layer 150 is generally formed of a material that, at the thickness used in photovoltaic cell 100, transports electrons to anode 160 and substantially blocks the transport of holes to anode 160. Examples of materials from which the hole blocking layer can be formed include LiF and metal oxides (e.g., zinc oxide, titanium oxide). In some embodiments, hole blocking layer 150 is formed of an electron donating compound, such as a nitrogen-containing compound, a phosphorus-containing compound, and/or a sulfur-containing compound. Examples of such electron donating compounds are described in commonly owned co-pending U.S. Provisional Application Ser. No. 60/926,459, the contents of which are hereby incorporated by reference. In some embodiments, photovoltaic cell 100 includes a layer containing such an electron donating compound (e.g., a nitrogen-containing compound) in addition to hole blocking layer 150. In certain embodiments, this additional layer is disposed between photoactive layer 140 and hole blocking layer 150. In certain embodiments, photovoltaic cell 100 can omit hole blocking layer 150.

Typically, hole blocking layer 150 is at least 0.02 micron (e.g., at least about 0.03 micron, at least about 0.04 micron, at least about 0.05 micron) thick and/or at most about 0.5 micron (e.g., at most about 0.4 micron, at most about 0.3 micron, at most about 0.2 micron, at most about 0.1 micron) thick.

Without wishing to be bound by theory, it is believed that when hole blocking layer 150 is formed of metal oxides (such as zinc oxide or titanium oxide), an additional layer containing an electron donating compound (e.g., a nitrogen-containing compound) between photoactive layer 140 and hole blocking layer 150 can facilitate the formation of ohmic contact between the metal oxide and photoactive layer 140 without UV light exposure, thereby reducing damage to photovoltaic cell 100 resulted from such exposure.

Photovoltaic cell 100 can optionally include substrate 170. Substrate 170 can be identical to or different from substrate 110. In some embodiments, substrate 170 can be formed of one or more suitable polymers, such as those described above. In certain embodiments, photovoltaic cell 100 can omit substrate 170.

In general, each of hole carrier layer 130, photoactive layer 140, hole blocking layer 150, and anode 160 can be prepared by a liquid-based coating process. The term “liquid-based coating process” mentioned herein refers to a process that uses a liquid-based coating composition. Examples of the liquid-based coating composition can be a solution, a dispersion, or a suspension. The concentration of a liquid-based coating composition can generally be adjusted as desired. In some embodiments, the concentration can be adjusted to achieve a desired viscosity of the coating composition or a desired thickness of the coating.

The liquid-based coating process can be carried out by using at least one of the following processes: solution coating, ink jet printing, spin coating, dip coating, knife coating, bar coating, spray coating, roller coating, slot coating, gravure coating, flexographic printing, or screen printing. Without wishing to bound by theory, it is believed that the liquid-based coating process can be readily used in a continuous manufacturing process, such as a roll-to-roll process, thereby significantly reducing the cost of preparing a photovoltaic cell. Examples of roll-to-roll processes have been described in, for example, commonly-owned co-pending U.S. Application Publication No. 2005-0263179, the contents of which are hereby incorporated by reference.

In some embodiments, when a layer (e.g., layer 130, 140, 150, or 160) includes inorganic semiconductor or conducting nanoparticles, the liquid-based coating process can be carried out by (1) mixing the nanoparticles (e.g., CIS or CIGS nanoparticles) with a solvent (e.g., an aqueous solvent or an anhydrous alcohol) to form a dispersion, (2) coating the dispersion onto a substrate, and (3) drying the coated dispersion. In certain embodiments, a liquid-based coating process for preparing a layer containing inorganic metal oxide nanoparticles can be carried out by (1) dispersing a precursor (e.g., a titanium salt) in a suitable solvent (e.g., an anhydrous alcohol) to form a dispersion, (2) coating the dispersion on a photoactive layer, (3) hydrolyzing the dispersion to form an inorganic semiconductor nanoparticles layer (e.g., a titanium oxide nanoparticles layer), and (4) drying the inorganic semiconductor material layer. In certain embodiments, the liquid-based coating process can be carried out by a sol-gel process.

In general, the liquid-based coating process used to prepare a layer containing an organic material can be the same as or different from that used to prepare a layer containing an inorganic material. In some embodiments, when a layer (e.g., layer 130, 140, 150, or 160) includes an organic material, the liquid-based coating process can be carried out by mixing the organic material with a solvent (e.g., an organic solvent) to form a solution or a dispersion, coating the solution or dispersion on a substrate, and drying the coated solution or dispersion. For example, an organic photoactive layer can be prepared by mixing an electron donor material (e.g., P3HT) and an electron acceptor material (e.g., PCBM) in a suitable solvent (e.g., xylene) to form a dispersion, coating the dispersion onto a substrate, and drying the coated dispersion.

The liquid-based coating process can be carried out at an elevated temperature (e.g., at least about 50° C., at least about 100° C., at least about 200° C., or at least about 300° C.). The temperature can be adjusted depending on various factors, such as the coating process and the coating composition used. For example, when preparing a layer containing inorganic nanoparticles, the nanoparticles can be sintered at a high temperature (e.g., at least about 300° C.) to form interconnected nanoparticles. On the other hand, when a polymeric linking agent (e.g., poly(n-butyl titanate)) is added to the inorganic nanoparticles, the sintering process can be carried out at a lower temperature (e.g., below about 300° C.).

In some embodiments, photovoltaic cell 100 can be prepared as follows: An ITO coated glass substrate can be cleaned by sonicating in an organic solvent (e.g., acetone and/or isopropanol) for a certain amount of time (e.g., 5-15 minutes). The substrate can then be treated with UV/ozone. A hole carrier layer (e.g., a PEDOT layer) can be coated on top of the ITO. After the layer is dried, a blend of an electron donor material (e.g., P3HT) and an electron acceptor material (e.g., PCBM) with a suitable weight ratio (e.g., 1-1.5:1) in an organic solvent (e.g., an aromatic solvent) can be coated at a certain temperature (e.g., 50-80° C.) to form a photoactive layer. A dispersion of electrically conductive particles (e.g., silver particles) coated with a self-assembled layer (e.g., hexadecanethiol) can subsequently coated (e.g., by slot coating) on the photoactive layer to form a photovoltaic cell.

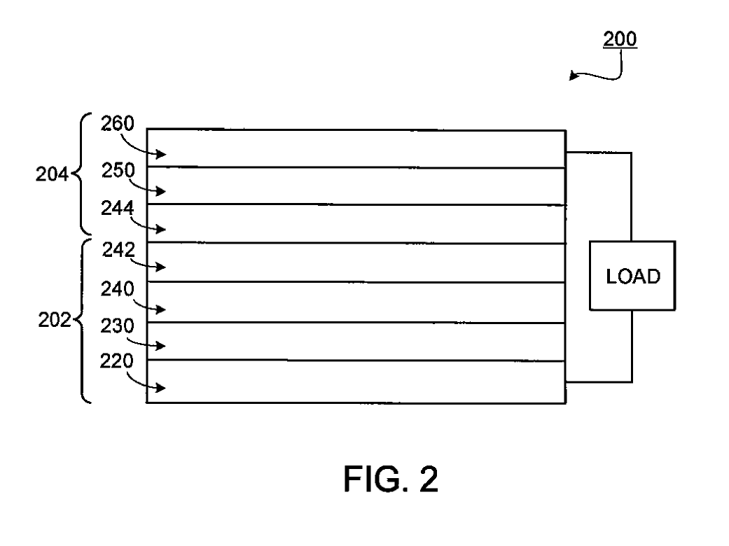

FIG. 2 shows a tandem photovoltaic cell 200 having two semi-cells 202 and 204. Semi-cell 202 includes a cathode 220, a hole carrier layer 230, a first photoactive layer 240, and a recombination layer 242. Semi-cell 204 includes a recombination layer 242, a second photoactive layer 244, a hole blocking layer 250, and an anode 260. An external load is connected to photovoltaic cell 200 via cathode 220 and anode 260. Depending on the production process and the desired device architecture, the current flow in a semi-cell can be reversed by changing the electron/hole conductivity of a certain layer (e.g., changing hole carrier layer 230 to a hole blocking layer). By doing so, a tandem cell can be designed such that the semi-cells in the tandem cells can be electrically interconnected either in series or in parallel.

A recombination layer refers to a layer in a tandem cell where the electrons generated from a first semi-cell recombine with the holes generated from a second semi-cell. Recombination layer 242 typically includes a p-type semiconductor material and an n-type semiconductor material. In general, n-type semiconductor materials selectively transport electrons and p-type semiconductor materials selectively transport holes. As a result, electrons generated from the first semi-cell recombine with holes generated from the second semi-cell at the interface of the n-type and p-type semiconductor materials.

In some embodiments, the p-type semiconductor material includes a polymer and/or a metal oxide. Examples of p-type semiconductor polymers include polythiophenes (e.g., poly(3,4-ethylene dioxythiophene) (PEDOT)), polyanilines, polycarbazoles, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxaline, polybenzoisothiazole, polybenzothiazole, polythienothiophene, poly(thienothiophene oxide), polydithienothiophene, poly(dithienothiophene oxide)s, polytetrahydroisoindoles, and copolymers thereof. The metal oxide can be an intrinsic p-type semiconductor (e.g., copper oxides, strontium copper oxides, or strontium titanium oxides) or a metal oxide that forms a p-type semiconductor after doping with a dopant (e.g., p-doped zinc oxides or p-doped titanium oxides). Examples of dopants includes salts or acids of fluoride, chloride, bromide, and iodide. In some embodiments, the metal oxide can be used in the form of nanoparticles.

In some embodiments, the n-type semiconductor material includes a metal oxide, such as a titanium oxide, a zinc oxide, a tungsten oxide, a molybdenum oxide, or a combination thereof. The metal oxide can be used in the form of nanoparticles. In other embodiments, the n-type semiconductor material includes a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof.

In some embodiments, the p-type and n-type semiconductor materials are blended into one layer. In certain embodiments, the recombination layer includes two layers, one layer including the p-type semiconductor material and the other layer including the n-type semiconductor material. In such embodiments, recombination layer 242 can also include a layer of mixed n-type and p-type semiconductor material at the interface of the two layers.

In some embodiments, recombination layer 242 includes at least about 30 wt % (e.g., at least about 40 wt % or at least about 50 wt %) and/or at most about 70 wt % (e.g., at most about 60 wt % or at most about 50 wt %) of the p-type semiconductor material. In some embodiments, recombination layer 242 includes at least about 30 wt % (e.g., at least about 40 wt % or at least about 50 wt %) and/or at most about 70 wt % (e.g., at most about 60 wt % or at most about 50 wt %) of the n-type semiconductor material.

Recombination layer 242 generally has a sufficient thickness so that the layers underneath are protected from any solvent applied onto recombination layer 242. In some embodiments, recombination layer 242 can have a thickness at least about 10 nm (e.g., at least about 20 nm, at least about 50 nm, or at least about 100 nm) and/or at most about 500 nm (e.g., at most about 200 nm, at most about 150 nm, or at most about 100 nm).

In general, recombination layer 242 is substantially transparent. For example, at the thickness used in a tandem photovoltaic cell 200, recombination layer 242 can transmit at least about 70% (e.g., at least about 75%, at least about 80%, at least about 85%, or at least about 90%) of incident light at a wavelength or a range of wavelengths (e.g., from about 350 nm to about 1,000 nm) used during operation of the photovoltaic cell.

Recombination layer 242 generally has a sufficiently low surface resistivity. In some embodiments, recombination layer 242 has a resistivity of at most about 1×10⁶ ohm/square (e.g., at most about 5×10⁵ ohm/square, at most about 2×10⁵ ohm/square, or at most about 1×10⁵ ohm/square).

Without wishing to be bound by theory, it is believed that recombination layer 242 can be considered as a common electrode between two semi-cells (e.g., one including cathode 220, hole carrier layer 230, photoactive layer 240, and recombination layer 242, and the other include recombination layer 242, photoactive layer 244, hole blocking layer 250, and anode 260) in photovoltaic cells 200. In some embodiments, recombination layer 242 can include an electrically conductive mesh material, such as those described above. An electrically conductive mesh material can provide a selective contact of the same polarity (either p-type or n-type) to the semi-cells and provide a highly conductive but transparent layer to transport electrons to a load.

In some embodiments, recombination layer 242 can be prepared by applying a blend of an n-type semiconductor material and a p-type semiconductor material on a photoactive layer. For example, an n-type semiconductor and a p-type semiconductor can be first dispersed and/or dissolved in a solvent together to form a dispersion or solution, which can then be coated on a photoactive layer to form a recombination layer.

In some embodiments, recombination layer 242 can include two or more layers with required electronic and optical properties for tandem cell functionality. For example, recombination layer 242 can include a layer that contains an n-type semiconductor material and a layer that contains a p-type semiconductor material. In some embodiments, the layer containing an n-type semiconductor material is disposed between photoactive layer 240 and the layer that contains a p-type semiconductor material. In some embodiments, when the n-type semiconductor material includes a metal oxide (e.g., zinc oxide or titanium oxide), an intermediate layer that includes a nitrogen-containing compound, a phosphorus-containing compound, or a sulfur-containing compound can be disposed between photoactive layer 240 and the layer containing the n-type semiconductor material to facilitate formation of ohmic contact between these two layers. The intermediate layer can be formed of the same material, or having the same characteristics, as those used in hole blocking layer 150. In certain embodiments, the layer containing an n-type semiconductor material can be replaced by the just-mentioned intermediate layer. In such embodiments, the intermediate layer can serve both as an electron injection layer and a hole blocking layer. In such embodiments, semi-cell 202 (e.g., including electrode 220, hole carrier layer 230, first photoactive layer 240, and an intermediate layer that can serve as a hole blocking layer) can have the layers with the same function arranged in the same order as those in semi-cell 204 (e.g., including a layer containing a p-type semiconductor material that can serve as a hole carrier layer, second photoactive layer 244, hole blocking layer 250, and electrode 260).

In some embodiments, a two-layer recombination layer can be prepared by applying a layer of an n-type semiconductor material and a layer of a p-type semiconductor material separately. For example, when titanium oxide nanoparticles are used as an n-type semiconductor material, a layer of titanium oxide nanoparticles can be formed by (1) dispersing a precursor (e.g., a titanium salt) in a solvent (e.g., an anhydrous alcohol) to form a dispersion, (2) coating the dispersion on a photoactive layer, (3) hydrolyzing the dispersion to form a titanium oxide layer, and (4) drying the titanium oxide layer. As another example, when a polymer (e.g., PEDOT) is used a p-type semiconductor, a polymer layer can be formed by first dissolving the polymer in a solvent (e.g., an anhydrous alcohol) to form a solution and then coating the solution on a photoactive layer.

Other components in tandem cell 200 can be identical to the corresponding components described with respect to photovoltaic cell 100. For example, tandem cell 200 can include anode 260 that is formed of the same materials (e.g., electrically conductive particles coated with a self-assembled layer) as noted above regarding anode 160 in photovoltaic cell 100.

In some embodiments, the semi-cells in a tandem cell are electrically interconnected in series. When connected in series, in general, the layers can be in the order shown in FIG. 2. In certain embodiments, the semi-cells in a tandem cell are electrically interconnected in parallel. When interconnected in parallel, a tandem cell having two semi-cells can include the following layers: a first cathode, a first hole carrier layer, a first photoactive layer, a first hole blocking layer (which can serve as an anode), a second hole blocking layer (which can serve as an anode), a second photoactive layer, a second hole carrier layer, and a second cathode. In such embodiments, the first and second hole blocking layers can be either two separate layers (such as those in a two-layer recombination layer 242) or can be one single layer (such as the layer in a one-layer recombination layer 242). In case the conductivity of the first and second hole blocking layer is not sufficient, an additional layer (e.g., an electrically conductive mesh layer) providing the required conductivity may be inserted.

In some embodiments, a tandem cell can include more than two semi-cells (e.g., three, four, five, six, seven, eight, nine, ten or more semi-cells). In certain embodiments, some semi-cells can be electrically interconnected in series and some semi-cells can be electrically interconnected in parallel.

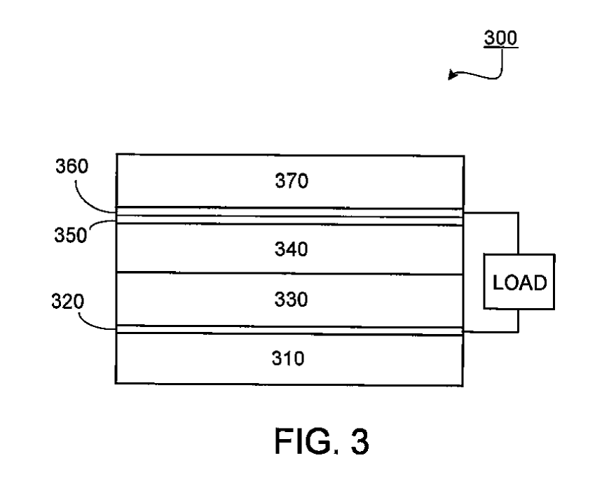

In some embodiments, the materials used to prepare anode 160 in photovoltaic cell 100 can be used to prepare an electrode in a dye-sensitized solar cell (DSSC). FIG. 3 shows DSSC 400 that includes a substrate 310, an electrode 320, a photoactive layer 330, a charge carrier layer 340, a catalyst layer 350, an electrode 360, a substrate 370, and an external load. Examples of DSSCs are discussed in U.S. patent application Ser. No. 11/311,805 filed Dec. 19, 2005 and U.S. patent application Ser. No. 11/269,956 filed on Nov. 9, 2005, the contents of which are hereby incorporated by reference. For example, photoactive layer 330 can include a photosensitized interconnected nanoparticle material. In some embodiments, the photosensitized interconnected nanoparticle material can include selenides, sulfides, tellurides, titanium oxides, tungsten oxides, zinc oxides, zirconium oxides, or combinations thereof. In certain embodiments, the materials used to prepare anode 160 in photovoltaic cell 100 can also be used to prepare an electrode in a tandem dye-sensitized solar cell.

While certain embodiments have been disclosed, other embodiments are also possible.

In some embodiments, while FIG. 1 shows that photovoltaic cell 100 includes cathode as a bottom electrode and anode as a top electrode, photovoltaic cell 100 can also include an anode as a bottom electrode and a cathode as a top electrode.

In some embodiments, photovoltaic cell 100 can include the layers shown in FIG. 1 in a reverse order. In other words, photovoltaic cell 100 can include these layers from the bottom to the top in the following sequence: a substrate 170, an anode 160, a hole blocking layer 150, a photoactive layer 140, a hole carrier layer 130, a cathode 120, and a substrate 110.

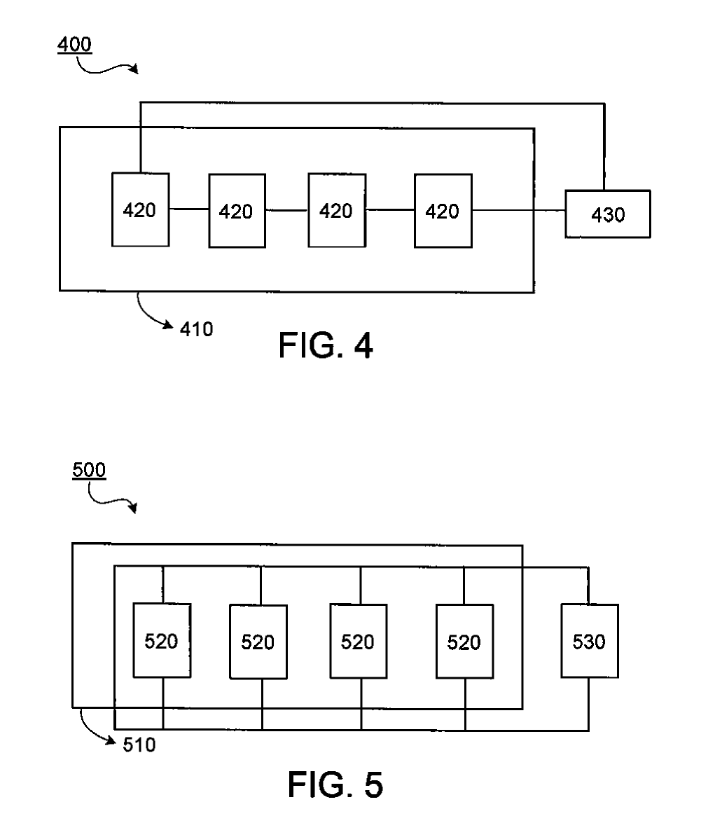

In some embodiments, multiple photovoltaic cells can be electrically connected to form a photovoltaic system. As an example, FIG. 4 is a schematic of a photovoltaic system 400 having a module 410 containing photovoltaic cells 420. Cells 420 are electrically connected in series, and system 400 is electrically connected to a load 430. As another example, FIG. 5 is a schematic of a photovoltaic system 500 having a module 510 that contains photovoltaic cells 520. Cells 520 are electrically connected in parallel, and system 500 is electrically connected to a load 530. In some embodiments, some (e.g., all) of the photovoltaic cells in a photovoltaic system can have one or more common substrates. In certain embodiments, some photovoltaic cells in a photovoltaic system are electrically connected in series, and some of the photovoltaic cells in the photovoltaic system are electrically connected in parallel.

While photovoltaic cells have been described above, in some embodiments, the polymers described herein can be used in other devices and systems. For example, the polymers can be used in suitable organic semiconductive devices, such as field effect transistors, photodetectors (e.g., IR detectors), photovoltaic detectors, imaging devices (e.g., RGB imaging devices for cameras or medical imaging systems), light emitting diodes (LEDs) (e.g., organic LEDs or IR or near IR LEDs), lasing devices, conversion layers (e.g., layers that convert visible emission into IR emission), amplifiers and emitters for telecommunication (e.g., dopants for fibers), storage elements (e.g., holographic storage elements), and electrochromic devices (e.g., electrochromic displays).

Other embodiments are in the claims.

1. An article, comprising:
a first electrode;
a second electrode comprising a plurality of electrically conductive particles, at least some of the electrically conductive particles being coated with a compound that comprises at least one moiety selected from the group consisting of thiol, siloxane, amino, nitrate, carboxylate, phosphate, and sulfonate; and
a photoactive layer between the first and second electrodes;
wherein the article is configured as a photovoltaic cell.

2. The article of claim 1, wherein substantially all of the electrically conductive particles are coated with the compound.

3. The article of claim 1, wherein the compound comprises a thiol moiety.

4. The article of claim 3, wherein the compound is an alkanethiol compound or a perfluorinated alkanethiol compound.

5. The article of claim 3, wherein the compound is of the formula R—SH, in which R is C₁-C₂₀ alkyl, C₂-C₂₀ alkenyl, C₂-C₂₀ alkynyl, C₃-C₂₀ cycloalkyl, C₃-C₂₀ cycloalkenyl, C₁-C₂₀ heterocycloalkyl, C₁-C₂₀ heterocycloalkenyl, aryl, or heteroaryl.

6. The article of claim 5, wherein R is C₁-C₁₀ alkyl optionally substituted with F.

7. The article of claim 3, wherein the compound is hexadecanethiol or 1H,1H,2H,2H-perfluorodecanethiol.

8. The article of claim 1, wherein the electrically conductive particles are formed of a metal.

9. The article of claim 8, wherein the metal is selected from the group consisting of silver, gold, platinum, palladium, copper, and an alloy thereof.

10. The article of claim 1, wherein the electrically conductive particles are formed of a metal oxide.

11. The article of claim 10, wherein the metal oxide comprises indium oxide, tin oxide, indium tin oxide, zinc oxide, magnesium oxide, or a mixture thereof.

12. The article of claim 1, wherein the electrically conductive particles have an average diameter of at least about 0.5 microns.

13. The article of claim 1, wherein the electrically conductive particles have an average diameter of at most about 10 microns.

14. The article of claim 1, wherein the second electrode further comprises a polymer.

15. The article of claim 14, wherein the polymer comprises a polyester, a polyvinyl chloride, a polyvinyl acetate, a poly(ethylene-vinyl acetate), a polyurethane, a poly(styrene-butadiene), a polyacrylic, or a copolymer thereof.

16. The article of claim 1, wherein the second electrode further comprises a surfactant.

17. The article of claim 1, wherein the photoactive layer comprises an electron donor material and an electron acceptor material.

18. The article of claim 17, wherein the electron donor material comprises a polymer selected from the group consisting of polythiophenes, polyanilines, polycarbazoles, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxaline, polybenzoisothiazole, polybenzothiazole, polythienothiophene, poly(thienothiophene oxide), polydithienothiophene, poly(dithienothiophene oxide)s, polytetrahydroisoindoles, and copolymers thereof.

19. The article of claim 18, wherein the electron donor material comprises a polymer selected from the group consisting of polythiophenes, polycyclopentadithiophenes, and copolymers thereof.

20. The article of claim 19, wherein the electron donor material comprises poly(3-hexylthiophene) or poly(cyclopentadithiophene-co-benzothiadiazole).

21. The article of claim 17, wherein the electron acceptor material comprises a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof.

22. The article of claim 21, wherein the electron acceptor material comprises a substituted fullerene.

23. The article of claim 22, wherein the substituted fullerene comprises PCBM.

24. The article of claim 1, wherein the photoactive layer comprises a photosensitized interconnected nanoparticle material.

25. The system of claim 24, wherein the photosensitized interconnected nanoparticle material comprises a material selected from the group consisting of selenides, sulfides, tellurides, titanium oxides, tungsten oxides, zinc oxides, zirconium oxides, and combinations thereof.

26. The article of claim 1, further comprising a hole carrier layer between the first electrode and the photoactive layer.

27. The article of claim 26, wherein the hole carrier layer comprises a polymer selected from the group consisting of polythiophenes, polyanilines, polycarbazoles, polyvinylcarbazoles, polyphenylenes, polyphenylvinylenes, polysilanes, polythienylenevinylenes, polyisothianaphthanenes, and copolymers thereof.

28. The article of claim 27, wherein the polymer comprises poly(3,4-ethylene dioxythiophene).

29. An article, comprising:
a first electrode;
a second electrode comprising a plurality of electrically conductive particles, at least some of the electrically conductive particles being coated with a compound that comprises at least one moiety selected from the group consisting of thiol, siloxane, amino, nitrate, carboxylate, phosphate, and sulfonate;
a first photoactive layer between the first and second electrodes; and
a second photoactive layer between the first photoactive layer and the second electrode; wherein the article is configured as a photovoltaic cell.

30. The article of claim 29, wherein substantially all of the electrically conductive particles are coated with the compound.

31. The article of claim 29, wherein the compound comprises a thiol moiety.

32. The article of claim 31, wherein the compound is an alkanethiol compound or a perfluorinated alkanethiol compound.

33. The article of claim 31, wherein the compound is of the formula R—SH, in which R is C₁-C₂₀ alkyl, C₂-C₂₀ alkenyl, C₂-C₂₀ alkynyl, C₃-C₂₀ cycloalkyl, C₃-C₂₀ cycloalkenyl, C₁-C₂₀ heterocycloalkyl, C₁-C₂₀ heterocycloalkenyl, aryl, or heteroaryl.

34. The article of claim 33, wherein R is C₁-C₁₀ alkyl optionally substituted with F.

35. The article of claim 31, wherein the compound is hexadecanethiol or 1H,1H,2H,2H-perfluorodecanethiol.

36. The article of claim 29, wherein the electrically conductive particles are formed of a metal.

37. The article of claim 36, wherein the metal is selected from the group consisting of silver, gold, platinum, palladium, copper, and an alloy thereof.

38. The article of claim 29, wherein the electrically conductive particles are formed of a metal oxide.

39. The article of claim 38, wherein the metal oxide comprises indium oxide, tin oxide, indium tin oxide, zinc oxide, magnesium oxide, or a mixture thereof.

40. The article of claim 29, wherein the electrically conductive particles have an average diameter of at least about 0.5 microns.

41. The article of claim 29, wherein the electrically conductive particles have an average diameter of at most about 10 microns.

42. The article of claim 29, wherein the second electrode further comprises a polymer.

43. The article of claim 42, wherein the polymer comprises a polyester, a polyvinyl chloride, a polyvinyl acetate, a poly(ethylene-vinyl acetate), a polyurethane, a poly(styrene-butadiene), a polyacrylic, or a copolymer thereof.

44. The article of claim 29, wherein the second electrode further comprises a surfactant.

45. The article of claim 29, wherein the article is configured as a tandem photovoltaic cell.

46-61. (canceled)

62. An article, comprising:
a first electrode;
a second electrode comprising a plurality of electrically conductive particles, at least some of the electrically conductive particles being coated with a self-assembled layer; and
a photoactive layer between the first and second electrodes;
wherein the article is configured as a photovoltaic cell.

63. An article, comprising:
a first electrode;
a second electrode comprising a plurality of electrically conductive particles, at least some of the electrically conductive particles being coated with a self-assembled layer;
a first photoactive layer between the first and second electrodes; and
a second photoactive layer between the first photoactive layer and the second electrode;
wherein the article is configured as a photovoltaic cell.

64-65. (canceled)
